(19) United States
(12) Patent Application Publication
(10) Pub. No.: US 2026/0155806 A1
(43) Pub. Date: Jun. 4, 2026

(54) INTERDIGITAL TRANSDUCER CAPACITOR WITH GROUND STRUCTURE

(71) Applicant: Skyworks Solutions, Inc., Irvine, CA (US)

(72) Inventors: Jun Sekimoto, Suita-Shi (JP); Yuya Hiramatsu, Neyagawa-Shi (JP)

(21) Appl. No.: 19/405,131

(22) Filed: Dec. 1, 2025

Related U.S. Application Data
(60) Provisional application No. 63/727,948, filed on Dec. 4, 2024.
(60) Provisional application No. 63/727,894, filed on Dec. 4, 2024.

(51) Int. Cl. H03H 9/64; H03H 9/145; H03H 9/25

(52) U.S. Cl. CPC H03H 9/64; H03H 9/145; H03H 9/25

(57) ABSTRACT

An interdigital transducer capacitor is disclosed. The interdigital transducer capacitor can include a piezoelectric layer, insulator, and an interdigital transducer electrode. The insulator can be included in a ground structure. The ground structure can include the insulator and a conductive ground layer. The insulator can be positioned between the piezoelectric layer and the conductive ground layer. The interdigital transducer electrode can be positioned between at least a portion of the piezoelectric layer and the ground structure. The insulator can have a Young's modulus greater than 80 GPa, and the interdigital transducer electrode can be positioned between at least the portion of the piezoelectric layer and the insulator.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/727,948, filed on Dec. 4, 2024, titled “INTERDIGITAL TRANSDUCER CAPACITOR WITH INSULATOR” and U.S. Provisional Patent Application No. 63/727,894, filed on Dec. 4, 2024, titled “INTERDIGITAL TRANSDUCER CAPACITOR WITH GROUND STRUCTURE” are hereby incorporated by reference under 37 CFR 1.57 in their entirety herein.

### BACKGROUND

### Field

Embodiments of this disclosure relate to interdigital transducer (IDT) capacitors.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A SAW resonator can include an interdigital transducer electrode on a piezoelectric substrate. The surface acoustic wave resonator can generate a surface acoustic wave on a surface of the piezoelectric layer on which the interdigital transducer electrode is disposed. A multilayer piezoelectric substrate surface acoustic wave (MPS-SAW) resonator is an example of the SAW resonator. Capacitors can be provided with the filter to provide additional capacitance for one or more resonators of the filter.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to an interdigital transducer capacitor including: a piezoelectric layer; an insulator having a Young's modulus greater than 80 GPa; and an interdigital transducer electrode between at least a portion of the piezoelectric layer and the insulator.

In some embodiments, the techniques described herein relate to an interdigital transducer capacitor wherein the insulator has the Young's modulus greater than 100 GPa.

In some embodiments, the techniques described herein relate to an interdigital transducer capacitor wherein the insulator has the Young's modulus greater than 140 GPa.

In some embodiments, the techniques described herein relate to an interdigital transducer capacitor wherein the insulator has the Young's modulus greater than 180 GPa.

In some embodiments, the techniques described herein relate to an interdigital transducer capacitor wherein the Young's modulus of the insulator is in a range between 140 GPa and 200 GPa.

In some embodiments, the techniques described herein relate to an interdigital transducer capacitor wherein the insulator is a polycrystalline layer.

In some embodiments, the techniques described herein relate to an interdigital transducer capacitor wherein the insulator is a polycrystalline lithium niobate layer.

In some embodiments, the techniques described herein relate to an interdigital transducer capacitor wherein the insulator has a thickness in a range between 100 nm and 500 nm.

In some embodiments, the techniques described herein relate to an interdigital transducer capacitor wherein the insulator is in contact with the piezoelectric layer.

In some embodiments, the techniques described herein relate to an interdigital transducer capacitor wherein the interdigital transducer electrode is in electrical communication with the piezoelectric layer.

In some embodiments, the techniques described herein relate to an interdigital transducer capacitor wherein the interdigital transducer electrode is pitch modulated.

In some embodiments, the techniques described herein relate to an interdigital transducer capacitor further including a support substrate, wherein the piezoelectric layer is positioned between the support substrate and the insulator.

In some embodiments, the techniques described herein relate to an interdigital transducer capacitor further including an intermediate layer between the support substrate and the piezoelectric layer.

In some aspects, the techniques described herein relate to an interdigital transducer capacitor including: a support substrate; a piezoelectric layer over the support substrate; an interdigital transducer electrode in electrical communication with the piezoelectric layer; and an insulator over the interdigital transducer electrode, the insulator including a polycrystalline material.

In some embodiments, the techniques described herein relate to an interdigital transducer capacitor wherein the insulator has a Young's modulus in a range between 80 GPa and 200 GPa.

In some embodiments, the techniques described herein relate to an interdigital transducer capacitor wherein the insulator is a polycrystalline lithium niobate layer.

In some embodiments, the techniques described herein relate to an interdigital transducer capacitor wherein the interdigital transducer electrode is pitch modulated.

In some aspects, the techniques described herein relate to a filter having a capacitor region and a resonator region, the filter including: an interdigital transducer capacitor in the capacitor region, the interdigital transducer capacitor including a piezoelectric layer, an interdigital transducer electrode, and an insulator having a Young's modulus greater than 80 GPa; and a surface acoustic wave resonator in the resonator region electrically coupled to the interdigital transducer capacitor.

In some embodiments, the techniques described herein relate to a filter wherein the insulator is not provided in the resonator region.

In some embodiments, the techniques described herein relate to a filter wherein the interdigital transducer electrode of the interdigital transducer capacitor is pitch modulated.

In some aspects, the techniques described herein relate to an interdigital transducer capacitor including: a piezoelectric layer; a ground structure including an insulator and a conductive ground layer, the insulator positioned between the piezoelectric layer and the conductive ground layer; and an interdigital transducer electrode between at least a portion of the piezoelectric layer and the ground structure.

In some embodiments, the techniques described herein relate to an interdigital transducer capacitor wherein the insulator has a Young's modulus greater than 80 GPa.

In some embodiments, the techniques described herein relate to an interdigital transducer capacitor wherein the insulator is a polyimide layer.

In some embodiments, the techniques described herein relate to an interdigital transducer capacitor wherein the insulator is a polycrystalline lithium niobate layer.

In some embodiments, the techniques described herein relate to an interdigital transducer capacitor wherein the insulator has a thickness in a range between 100 nm and 500 nm.

In some embodiments, the techniques described herein relate to an interdigital transducer capacitor wherein the insulator is in contact with the piezoelectric layer.

In some embodiments, the techniques described herein relate to an interdigital transducer capacitor wherein the conductive ground layer includes molybdenum, aluminum, titanium, or tungsten.

In some embodiments, the techniques described herein relate to an interdigital transducer capacitor wherein the conductive ground layer and the interdigital transducer electrode include a same material.

In some embodiments, the techniques described herein relate to an interdigital transducer capacitor wherein the conductive ground layer has a thickness in a range between 50 nm and 300 nm.

In some embodiments, the techniques described herein relate to an interdigital transducer capacitor wherein the conductive ground layer is positioned on a surface of the insulator.

In some embodiments, the techniques described herein relate to an interdigital transducer capacitor wherein the conductive ground layer conformally covers the insulator.

In some embodiments, the techniques described herein relate to an interdigital transducer capacitor further includes a conductive via at least partially through a thickness of the insulator and electrically connected to the conductive ground layer.

In some embodiments, the techniques described herein relate to an interdigital transducer capacitor wherein the interdigital transducer electrode is in electrical communication with the piezoelectric layer.

In some embodiments, the techniques described herein relate to an interdigital transducer capacitor wherein the interdigital transducer electrode is pitch modulated.

In some embodiments, the techniques described herein relate to an interdigital transducer capacitor further including a support substrate, wherein the piezoelectric layer is positioned between the support substrate and the insulator.

In some embodiments, the techniques described herein relate to an interdigital transducer capacitor further including an intermediate layer between the support substrate and the piezoelectric layer.

In some aspects, the techniques described herein relate to an interdigital transducer capacitor including: a piezoelectric layer; an insulator over the piezoelectric layer; a conductive layer over the insulator; and an interdigital transducer electrode between at least a portion of the piezoelectric layer and the insulator.

In some embodiments, the techniques described herein relate to an interdigital transducer capacitor wherein the insulator has a Young's modulus greater than 80 GPa.

In some embodiments, the techniques described herein relate to an interdigital transducer capacitor wherein the interdigital transducer electrode is pitch modulated.

In some aspects, the techniques described herein relate to a filter having a capacitor region and a resonator region, the filter including: an interdigital transducer capacitor in the capacitor region, the interdigital transducer capacitor including a piezoelectric layer, a ground structure, and an interdigital transducer electrode, the ground structure including an insulator and a conductive ground layer, the insulator being positioned between the piezoelectric layer and the conductive ground layer, and the interdigital transducer electrode being positioned between at least a portion of the piezoelectric layer and the ground structure; and a surface acoustic wave resonator in the resonator region electrically coupled to the interdigital transducer capacitor.

### BRIEF DESCRIPTION OF THE DRAWINGS

Embodiments of this disclosure will now be described, by way of non-limiting example, with reference to the accompanying drawings.

FIG. 1A is a schematic top plan view of an IDT capacitor according to an embodiment.

FIG. 1B is a schematic cross-sectional side view of the IDT capacitor of FIG. 1A.

FIG. 2A is a schematic top plan view of a surface acoustic wave (SAW) device that includes the IDT capacitor of FIGS. 1A and 1B and a resonator.

FIG. 2B is a schematic cross-sectional side view of the SAW device of FIG. 2A.

FIG. 3 is a schematic top plan view of an example layout of a filter that includes the SAW device of FIGS. 2A and 2B.

FIG. 4A is a graph showing simulated admittance results of IDT capacitors (IDT capacitors A, B, and C).

FIG. 4B is a graph showing simulated static capacitance values and relative capacitance increase rates of the IDT capacitors A, B, and C.

FIG. 5 is a graph showing simulated admittance results of the IDT capacitor of FIGS. 1A and 1B in various embodiments.

FIG. 6 is a schematic cross-sectional side view of an IDT capacitor according to an embodiment.

FIG. 7 is a schematic cross-sectional side view of a SAW device that includes the IDT capacitor of FIG. 6 and the resonator.

FIG. 8A is a graph showing simulated admittance results of IDT capacitors (IDT capacitors A, D, and E).

FIG. 8B is a graph showing simulated static capacitance values and relative capacitance increase rates of the IDT capacitors A, D, and E.

FIG. 9 is a graph showing simulated admittance results of the IDT capacitor of FIG. 6 in various embodiments.

FIG. 10 is a schematic cross-sectional side view of an IDT capacitor according to another embodiment.

FIG. 11 is a schematic cross-sectional side view of an IDT capacitor according to another embodiment.

FIG. 12A is a schematic diagram of an example multiplexer that includes surface acoustic wave devices according to an embodiment.

FIG. 12B is a schematic diagram of another multiplexer that includes surface acoustic wave devices according to an embodiment.

FIG. 13 is a schematic diagram of a radio frequency module that includes a surface acoustic wave component.

FIG. 14 is a schematic diagram of a radio frequency module that includes a surface acoustic wave resonator according to an embodiment.

FIG. 15 is a schematic block diagram of a module that includes duplexers and an antenna switch.

FIG. 16A is a schematic block diagram of a module that includes a power amplifier, a radio frequency switch, and duplexers, in accordance with one or more embodiments.

FIG. 16B is a schematic block diagram of a module that includes filters, a radio frequency switch, and a low noise amplifier, according to an embodiment.

FIG. 17A is a schematic diagram of a wireless communication device that includes filters in a radio frequency front end, according to an embodiment.

FIG. 17B is a schematic diagram of a wireless communication device.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Any features of the SAW resonators discussed herein can be implemented in any suitable SAW device such as a multilayer piezoelectric substrate surface acoustic wave (MPS-SAW) device.

A capacitor can provide additional capacitance in parallel or in series with a SAW resonator of a filter. Capacitors can be used for various purposes in filters and/or other electronic circuits, such as tuning the resonant frequency or providing impedance matching. The capacitors can be coupled with SAW resonators to achieve desired electrical characteristics. For example, a capacitor in parallel with a SAW resonator of a filter can shift (increase or decrease) the coupling factor (kt²) and improve the skirt performance and the insertion loss of the filter. In some applications such a capacitor is provided separately from the SAW resonator. The separately provided capacitor can introduce, for example, losses in the filter.

An interdigital transducer capacitor can enable integration of the capacitor with a resonator on a common piezoelectric layer. Such integration can lower losses in the filter. In an IDT capacitor, a larger static capacitance can be beneficial for enhancing signal strength by allowing a greater charge storage capacity, which improves the coupling of the transducer to the acoustic wave medium. However, it can be challenging to provide the interdigital transducer (IDT) capacitor that generates relatively low or no resonance and has a relatively large static capacitance without increasing the capacitor size.

Aspects of the present disclosure relate to interdigital transducer (IDT) capacitors that generate relatively low or no resonance and/or have a relatively large static capacitance. An IDT capacitor can include a piezoelectric layer, an insulator and an interdigital transducer electrode between at least a portion of the piezoelectric layer and the insulator. The insulator can have a relatively high Young's modulus. For example, the insulator can include a material that has a Young's modulus greater than 80 GPa. The material of the insulator can be, for example, polycrystalline lithium niobate. In some embodiments, the interdigital transducer capacitor can include a ground structure including the insulator and a conductive ground layer. The insulator can be positioned between the piezoelectric layer and the conductive ground layer. The insulator and/or the conductive ground layer can suppress generation of unwanted acoustic resonance by the interdigital transducer electrode of the capacitor and/or provide a relatively large static capacitance as compared to a similar IDT capacitor that does not include the insulator and the conductive ground layer.

The Young's modulus, also known as the elastic modulus, is a fundamental mechanical property of solid materials that measures their stiffness or elasticity under tensile or compressive stress. For example, the Young's modulus indicates how much a material will deform when subjected to a load. A material with a higher Young's modulus value is stiffer and deforms less under the same applied force.

The Young's modulus (E) is defined as the ratio of stress (σ) to strain (ε) in the linear elastic region of a material:

$$E = σ / ε$$

Where: σ is the tensile or compressive stress (force per unit area); and ε is the axial strain (proportional deformation).

This relationship is also known as Hooke's Law. Young's modulus is typically measured in pascals (Pa) or gigapascals (GPa) in the International System of Units (SI).

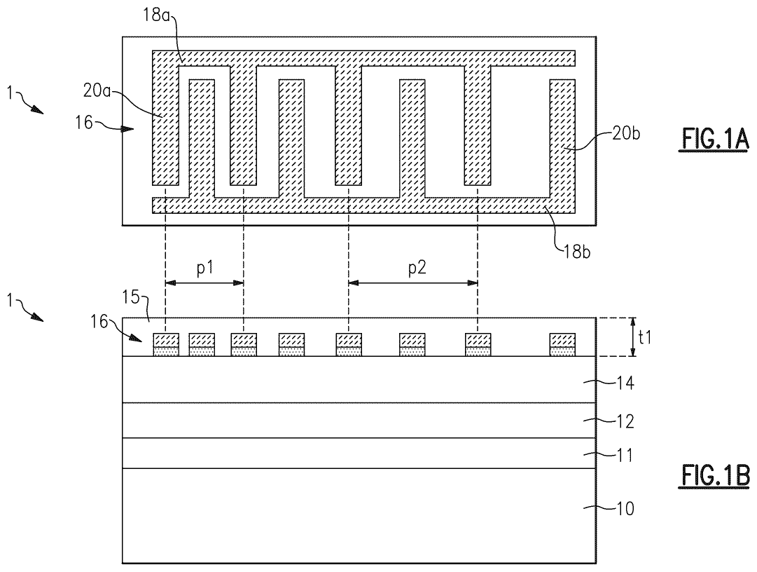

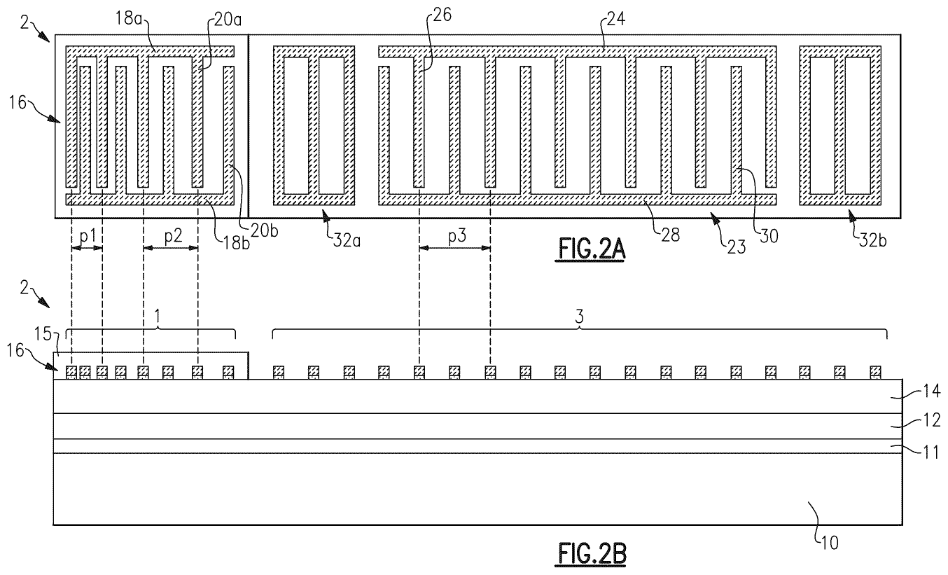

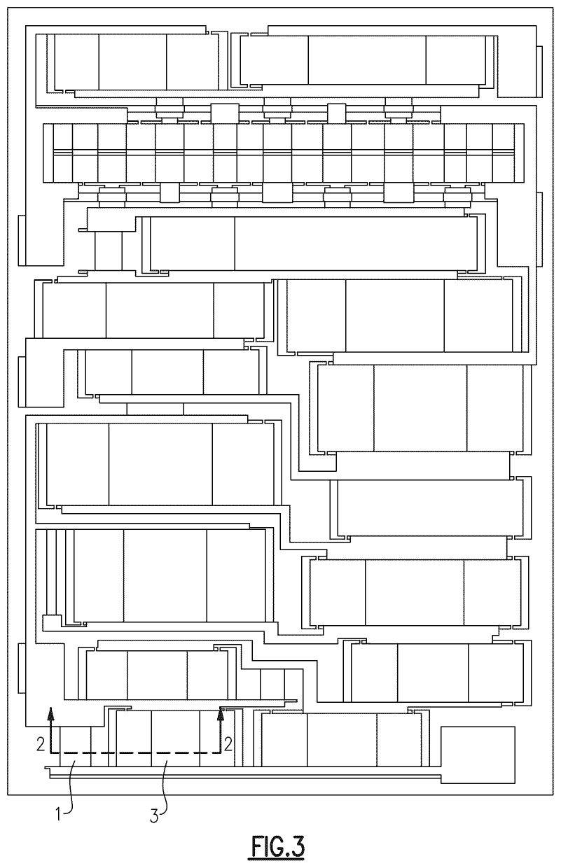

FIG. 1A is a schematic top plan view of an IDT capacitor 1 according to an embodiment. FIG. 1B is a schematic cross-sectional side view of the IDT capacitor 1. FIG. 2A is a schematic top plan view of a surface acoustic wave (SAW) device 2 that includes the IDT capacitor 1 and a resonator 3. FIG. 2B is a schematic cross-sectional side view of the SAW device 2. The SAW device 2 can be an MPS-SAW device, for example, as illustrated in FIGS. 2A and 2B. The SAW device 2 can be part of an acoustic wave filter.

The SAW device 2 can include a support substrate 10, an intermediate structure that can include intermediate layers 11, 12 over the support substrate 10, and a piezoelectric layer 14 over the intermediate layer 12. The SAW device 2 has a capacitor region corresponding to the IDT capacitor 1 and a resonator region corresponding to the resonator 3.

The IDT capacitor 1 can also include a cover layer (e.g., an insulator 15) over the piezoelectric layer 14. The IDT capacitor 1 can include an IDT electrode between at least a portion of the piezoelectric layer 14 and the insulator 15. The IDT electrode 16 can include a bus bar 18a, capacitor fingers 20a that extend from the bus bar 18a, a bus bar 18b, and capacitor fingers 20b that extend from the bus bar 18b. In FIGS. 1A and 2A, a portion of the insulator 15 is made transparent to show the IDT electrode 16 of the IDT capacitor 1. In some applications, the IDT electrode 16 can be in electrical communication with the piezoelectric layer 14.

The resonator 3 can include an IDT electrode 23 that includes a bus bar 24, resonator fingers 26 that extend from the bus bar 24, a bus bar 28, and resonator fingers 30 that extend from the bus bar 28, and a pair of acoustic reflectors 32a, 32b. The IDT electrode 23 is in electrical communication with the piezoelectric layer 14. The support substrate 10, the intermediate layers 11, 12, and the piezoelectric layer 14 can together define an MPS.

The insulator 15 can suppress generation of unwanted acoustic resonance by the interdigital transducer electrode of the capacitor and/or provide a relatively large static capacitance as compared to a similar IDT capacitor that does not include the insulator. In some embodiments, the insulator 15 can be in contact with the piezoelectric layer 14 and/or the IDT electrode 16 of the IDT capacitor 1.

The insulator 15 can include any suitable dielectric material. In some embodiments, the insulator 15 can have a Young's modulus greater than 80 GPa, greater than 100 GPa, greater than 140 GPa, or greater than 180 GPa. For example, the Young's modulus of the insulator 15 can be in a range between 80 GPa and 300 GPa, 80 GPa and 250 GPa, 80 GPa and 200 GPa, 100 GPa and 250 GPa, 140 GPa and 200 GPa, or 180 GPa and 200 GPa. In some embodiments, the insulator 15 can include a polycrystalline layer, such as a polycrystalline lithium niobate layer or a polycrystalline lithium tantalate layer. In some other embodiments, the insulator 15 can include a polyimide layer.

The insulator 15 of the IDT capacitor 1 has a thickness t1. For example, the thickness t1 of the insulator 15 can be in a range between 100 nm and 500 nm, 75 nm and 500 nm, or 100 nm and 300 nm. In some embodiments, the thickness t1 of the insulator 15 can be greater than a thickness of the IDT electrode 16.

Because the capacitor 1 with the insulator 15 can have a higher capacitance than a similar capacitor that does not include the insulator 15, a size of the capacitor 1 can be smaller than the similar capacitor that does not include the insulator 15 and still have the same capacitance. Therefore, a capacitor with a desired capacitance can be designed with a reduced size when the principles and advantages disclosed herein regarding the insulator are implemented.

In some embodiments, the IDT electrode 16 of the IDT capacitor 1 can be pitch modulated. The capacitor fingers 20a of the IDT capacitor 1 have a first pair of adjacent capacitor fingers extending from the bus bar 18a with a first pitch p1 and a second pair of adjacent capacitor fingers 20a extending from the bus bar 18a with a second pitch p2 different from the first pitch p1. The second pitch p2 can be, for example, at least 3%, at least 5%, or at least 8% greater than the first pitch p1. The second pitch p2 can be, for example, less than 10%, less than 15%, less than 20% greater than the first pitch p1. The second pitch p2 can be, for example, at least 0.1 micrometer greater, at least 0.2 micrometers greater, or at least 0.3 micrometers greater than the first pitch p1.

A pitch p3 of the resonator fingers 26, 30 of the IDT electrode 23 can be different from both the first pitch p1 and the second pitch p2 of the capacitor 1. In some embodiments, most or all of the pitches of adjacent capacitor fingers 20a, 20b of the capacitor 1 can be smaller than the pitch p3 of the resonator fingers 26, 30 of the IDT electrode 23. The smaller pitch can produce a larger capacitance density in the capacitor 1. In some other embodiments, most or all of the pitches of adjacent capacitor fingers 20a, 20b of the capacitor 1 can be greater than a pitch p3 of the resonator fingers 26, 30 of the IDT electrode 23. There are fewer capacitor fingers 20a, 20b of the capacitor 1 than resonator fingers 26, 30 of the IDT electrode 23. Although not shown in FIG. 2A, the capacitor 1 may have a smaller aperture than the resonator 3.

Although two pairs of adjacent capacitor fingers are described for illustrative purposes, some or all pitches of the capacitor fingers 20a, 20b may have different pitches. The capacitor fingers 20b can have the same or similar profile as the capacitor fingers 20a. A pitch of fingers sets the wavelength λ or L of an acoustic wave that the fingers can generate. Because the first pitch p1 and the second pitch p2 are different, the first pair of adjacent capacitor fingers and the second pair of adjacent capacitor fingers generate acoustic waves of different frequencies. Accordingly, the IDT capacitor 1 can generate little or no aggregate resonance. The IDT capacitor 1 can be integrated with the resonator 3 with relatively small or no interference with the performance of the resonator 3. As illustrated, unlike the resonator 3, the IDT capacitor 1 does not include an acoustic reflector. However, in some applications, the IDT capacitor may include an acoustic reflector.

The pitch profile of the capacitor fingers 20a, 20b can be modulated in any suitable manner. For example, the capacitor fingers 20a, 20b can have a gradation pitch in which the pitches of adjacent capacitor fingers 20a, 20b are gradually changed. As another example, the capacitor fingers 20a, 20b can be randomly distributed to have random pitches or pseudo-randomly distributed.

The IDT electrodes (the IDT electrode 16 of the capacitor 1; and the IDT electrode 23 of the resonator 3) can include any suitable IDT electrode material. For example, the electrodes can include molybdenum (Mo), aluminum (Al), copper (Cu), Magnesium (Mg), titanium (Ti), tungsten (W), the like, or any suitable combination thereof. The IDT electrodes can have a multilayer structure. For example, the IDT electrodes 23 illustrated in FIG. 2A, and 2B have a multilayer structure that includes a first layer and a second layer. One of the first layer and the second layer can be more electrically conductive than the other, and the other one can be more durable (e.g., resistive to metal fatigue). In some embodiments, the first layer or the second layer can have a higher mass density and/or higher Young's modulus than the other. The interdigital transducer electrodes can be formed with (e.g., formed on or at least partially in) the piezoelectric layer 14. The piezoelectric layer 14 and the electrodes can be provided in any suitable manner. For example, the piezoelectric layer 14 and the electrodes can be provided in sequence. When the electrodes are provided at least partially in the piezoelectric layer 14, the piezoelectric layer 14 can be partially etched and/or provided in a plurality of steps.

The support substrate 10 can have a relatively high acoustic impedance. For example, the support substrate 10 can have a higher impedance than an impedance of the piezoelectric layer 14 and a higher thermal conductivity than a thermal conductivity of the piezoelectric layer 14. The support substrate 10 can be a silicon substrate, for example. The support substrate 10 can be formed of quartz, spinel, borosilicate, or the like. The support substrate 10 can include a dielectric material. For example, the support substrate 10 can include sapphire or aluminum oxide (Al₂O₃). As compared to some other materials, such as silicon, sapphire has lower or no parasitic surface conductance as sapphire is dielectric. The multilayer piezoelectric substrate (MPS) that includes a sapphire support substrate can be referred to as a sapphire MPS.

The intermediate layer 11 can be, for example, a trap-rich layer that can suppress the parasitic surface conductivity at a surface of the support substrate 10 while improving the quality factor (Q) as compared to a similar device without a trap-rich layer. In some embodiments, the intermediate layer 11 can be a polycrystalline silicon layer. In some embodiments, the intermediate layer 11 can be a doped region of the support substrate 10.

The intermediate layer 12 can be, for example, a single crystal layer. In some embodiments, the intermediate layer 12 can be a silicon oxide layer (e.g., a silicon dioxide (SiO₂)) layer. In some embodiments, the intermediate layer 12 can function as an adhesion layer. In some embodiments, a thickness of the intermediate layer 12 can be the same as, generally similar to, or thinner than the thickness of the piezoelectric layer 14.

The piezoelectric layer 14 can include any suitable piezoelectric layer, such as a lithium based piezoelectric layer. Example lithium based piezoelectric materials include lithium tantalate and lithium niobate. In some embodiments, the piezoelectric layer 14 can be a lithium tantalate (LT) layer. For example, the piezoelectric layer 14 can be an LT layer having a cut angle of 20° (20° Y-cut X-propagation LT), a cut angle of 60° (60° Y-cut X-propagation LT), or a cut angle in a range from 20° to 60°. For example, the piezoelectric layer 14 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 14. For example, the piezoelectric layer 14 can be an LN layer having a cut angle of about 118° (118° Y-cut X-propagation LN) or more or a cut angle of about 132° (132Y-cut X-propagation LN) or less. For example, the piezoelectric layer 14 can be 125±20° Y-cut LN, 125±15° Y-cut LN, 125±10° Y-cut LN, or 125±5° Y-cut LN. A thickness of the piezoelectric layer 14 can be selected based on a wavelength λ or L of a surface acoustic wave generated by the resonator 3 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 14 can be sufficiently thick to avoid significant frequency variation. For example, the thickness of the piezoelectric layer 14 can be in a range of 0.1 L to 0.5 L, 0.1 L to 0.3 L, or 0.1 L to 0.2 L. Selecting the thickness of the piezoelectric layer 14 from these ranges can be significant in avoiding significant frequency variation and providing sufficient temperature coefficient of frequency for the SAW device 2. In some embodiments, the piezoelectric layer 14 can include lithium tantalate (LT) and lithium niobate (LN).

The IDT capacitor 1 and the resonator 3 can be positioned in any suitable manner in the SAW device 2. As illustrated, the IDT capacitor 1 can be positioned along a wave propagation direction (e.g., in a longitudinal direction) of the resonator 3. In some embodiments, the capacitor 1 can be coupled in parallel with the resonator 3. The SAW device 2 can be implemented as part of a filter. The resonator 3 can be a series resonator or a shunt resonator in the filter.

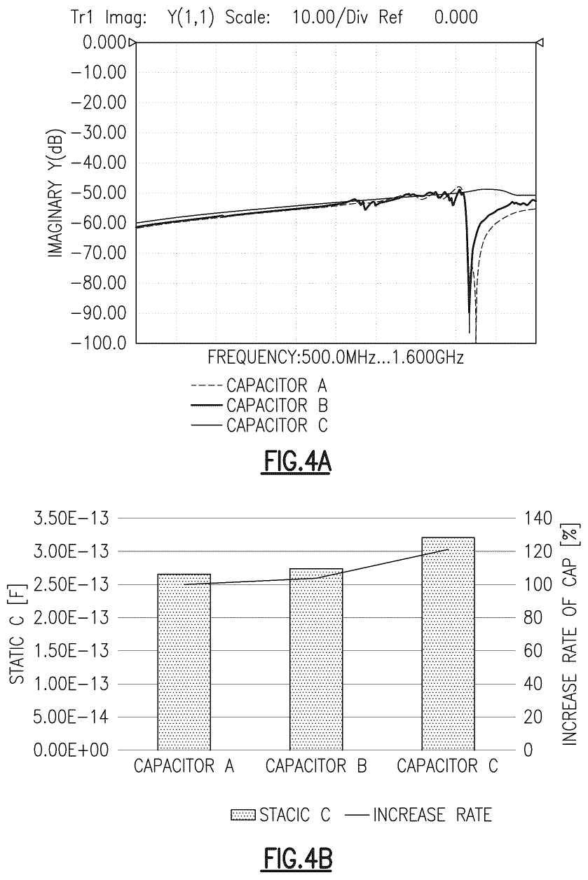

FIG. 3 is a schematic top plan view of an example layout of a filter 4 that includes the SAW device 2. The filter 4 can include a plurality of resonators configured to filter a radio frequency signal. In some embodiments, an area of the resonator 3 can be greater than an area of the IDT capacitor 1. A length of the resonator 3 can be greater than a length of the IDT capacitor 1 in a direction of acoustic wave propagation in the resonator 3. In some embodiments, the IDT capacitor 1 can be smaller than any of the plurality of resonators in the filter 4.

The IDT capacitor 1 can be coupled to a resonator (e.g., the resonator 3) in a filter (e.g., the filter 4) to shift (increase or decrease) the coupling factor (kt²) and improve the skirt performance and the insertion loss of the filter. The IDT capacitors disclosed herein can have a relatively high capacitance and/or generate relatively low or no resonance.

FIG. 4A is a graph showing simulated admittance results of IDT capacitors (IDT capacitors A, B, and C), which represent the capacitance of the IDT capacitors. FIG. 4B is a graph showing simulated static capacitance values of the IDT capacitors A, B, and C used in the simulations of FIG. 4A and relative capacitance increase rates of the IDT capacitors A, B, and C. The IDT capacitor A includes a 1000 nm thick silicon substrate, an 800 nm thick silicon dioxide (SiO₂) layer over the silicon substrate, a 100 nm thick lithium tantalate (LT) layer over the SiO₂ layer, and an aluminum-molybdenum dual layer IDT electrode on the piezoelectric layer. The IDT capacitors B and C are examples of the IDT capacitor 1. The IDT capacitor B includes a polyimide layer as the insulator 15 over the structure of IDT capacitor A, and the IDT capacitor C includes a polycrystalline lithium niobate layer as the insulator 15 over the structure of IDT capacitor A. The IDT capacitors A, B, and C include 10 pairs of IDT fingers and the IDT fingers are pitch modulated such that the smallest pitch is 90% of the largest pitch in the IDT fingers.

The simulation results of FIGS. 4A and 4B indicate that the static capacitance of the capacitor B is about 3% greater than the static capacitance of the capacitor A, and the static capacitance of the capacitor C is about 20% greater than the static capacitance of the capacitor A. Therefore, the capacitor B that includes the polyimide layer as the insulator 15 and the capacitor C that includes the polycrystalline lithium niobate layer as the insulator 15 can have greater static capacitance than the capacitor A while having the same capacitor size, or have the same capacitance as the capacitor A with a reduced capacitor size.

The simulation results of FIG. 4A also indicate that the acoustic resonance of the IDT capacitors B and C are suppressed as compared to the IDT capacitor A. The acoustic resonance of the IDT capacitor C is significantly reduced. The reduction in the acoustic resonance can be due to, at least in part on, the relatively high Young's modulus of the polycrystalline lithium niobate layer. In some embodiments, material of the insulator 15 can be selected based at least in part on the Young's modulus of the material.

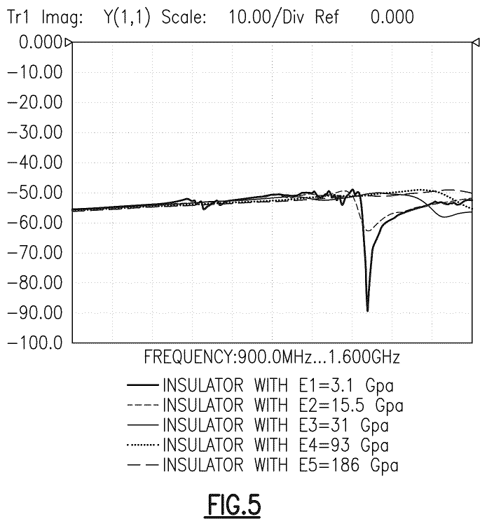

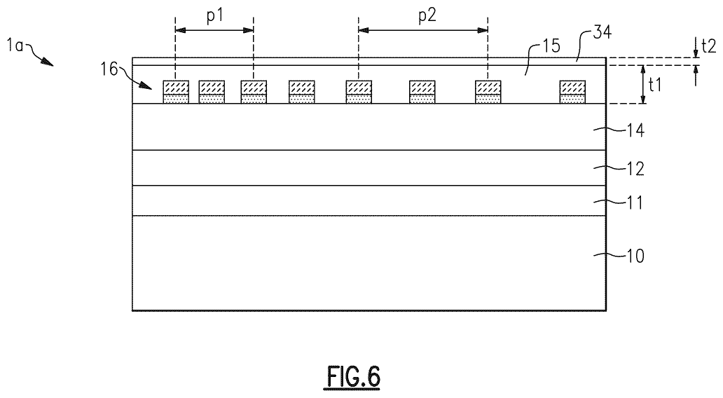

FIG. 5 is a graph showing simulated admittance results of the IDT capacitor 1 with the insulator 15 having different Young's modulus values. In FIG. 5, the IDT capacitor 1 with the insulator 15 having five different Young's modulus values E1=3.1 GPa, E2=15.5 GPa, E3=31 GPa, E4=93 GPa, and E5=186 GPa are used.

FIG. 5 indicates that when the Young's modulus is greater, the acoustic resonance in the IDT capacitor 1 can be suppressed more. In some embodiments, it can be significant to select the material of the insulator 15 that has a Young's modulus greater than 30 GPa, greater than 80 GPa, greater than 100 GPa, greater than 140 GPa, or greater than 180 GPa. For example, the Young's modulus of the insulator 15 can be in a range between 30 GPa and 300 GPa, 80 GPa and 300 GPa, 80 GPa and 250 GPa, 80 GPa and 200 GPa, 100 GPa and 250 GPa, 140 GPa and 200 GPa, or 180 GPa and 200 GPa.

The performance of the IDT capacitor 1 can be further improved by implementing a ground layer. For example, a ground layer can be provided over the insulator 15 to further increase the static capacitance and/or reduce the acoustic resonance in an IDT capacitor. Such embodiments will be described hereinafter.

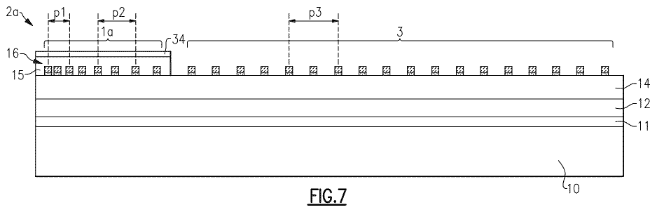

FIG. 6 is a schematic cross-sectional side view of an IDT capacitor 1a according to an embodiment. FIG. 7 is a schematic cross-sectional side view of a SAW device 2a that includes the IDT capacitor 1a and the resonator 3. Unless otherwise noted, the components shown in FIGS. 6 and 7 may be structurally and/or functionally the same as or generally similar to like components disclosed herein. The IDT capacitor 1a is generally similar to the IDT capacitor 1 except that the IDT capacitor 1a also includes a ground layer 34.

The insulator 15 and the ground layer 34 can together be part of a ground structure. In some embodiments, the ground layer 34 can be positioned on or over a surface of the insulator 15. The ground layer 34 can be electrically connected to a ground line in the SAW device 2a. The ground line may be formed with the piezoelectric layer 14, in some embodiments. The insulator 15 can be positioned between the ground layer 34 and the piezoelectric layer 14.

The ground layer 34 can include any suitable conductive material. For example, the ground layer 34 can include a metal, such as molybdenum, aluminum, titanium, or tungsten. In some embodiments, the ground layer 34 and the IDT electrode 16 can include a same material. The conductive ground layer 34 has a thickness t2. The thickness t2 can be any suitable thickness. For example, the thickness t2 of the conductive ground layer 34 can be in a range between 25 nm and 300 nm, 50 nm and 300 nm, 75 nm and 250 nm, or 100 nm and 200 nm. In some embodiments, the thickness t2 can be thinner than the thickness t1 of the insulator 15. The ground layer 34 can have any suitable shape. For example, the ground layer 34 can be a plate or a patterned layer.

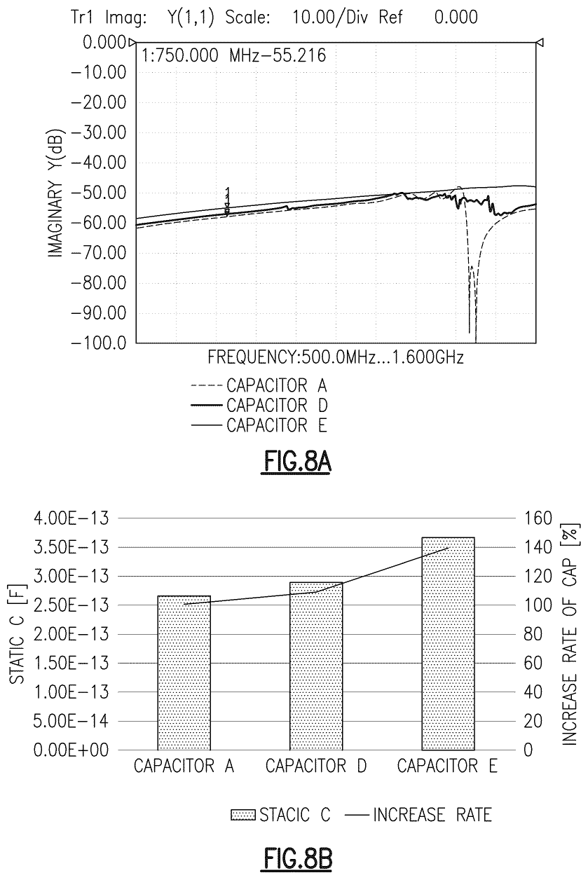

FIG. 8A is a graph showing simulated admittance results of IDT capacitors (IDT capacitors A, D, and E), which represent the capacitance of the IDT capacitors. FIG. 8B is a graph showing simulated static capacitance values of the IDT capacitors A, D, and E used in the simulations of FIG. 8A and relative capacitance increase rates of the IDT capacitors A, D, and E. The IDT capacitor A is the same as that used in FIGS. 4A and 4B. The IDT capacitors D and E are examples of the IDT capacitor 1a. The IDT capacitor D includes a polyimide layer as the insulator 15 over the structure of IDT capacitor A, and a 200 nm molybdenum layer as the ground layer 34 over the insulator 15. The IDT capacitor E includes a polycrystalline lithium niobate layer as the insulator 15 over the structure of IDT capacitor A, and a 200 nm molybdenum layer as the ground layer 34 over the insulator 15. The IDT capacitors A, D, and E include 10 pairs of IDT fingers and the IDT fingers are pitch modulated such that the smallest pitch is 90% of the largest pitch in the IDT fingers.

The simulation results of FIGS. 8A and 8B indicate that the static capacitance of the capacitor D is about 9% greater than the static capacitance of the capacitor A, and the static capacitance of the capacitor E is about 39% greater than the static capacitance of the capacitor A. Therefore, the capacitors D and E that include the ground structure can have greater static capacitance than the capacitor A while having the same capacitor size, or have the same capacitance as the capacitor A with a reduced capacitor size. FIGS. 4A, 4B, 8A and 8B also indicate that the capacitors D and E that include the ground layer 34 can have greater static capacitance than the capacitors B and C while having the same capacitor size, or have the same capacitance as the capacitors B and C with a reduced capacitor size.

The simulation results of FIG. 8A also indicate that the acoustic resonance of the IDT capacitors D and E are suppressed as compared to the IDT capacitor A. FIGS. 4A and 8A also indicate that the acoustic resonance of the IDT capacitors D and E are suppressed as compared to the IDT capacitors B and C.

Accordingly, the ground structure that includes the insulator 15 and the ground layer 34 can beneficially increase the static capacitance and/or reduce the acoustic resonance in an IDT capacitor. The material of the ground layer 34 can affect the acoustic response of the IDT capacitor 1a.

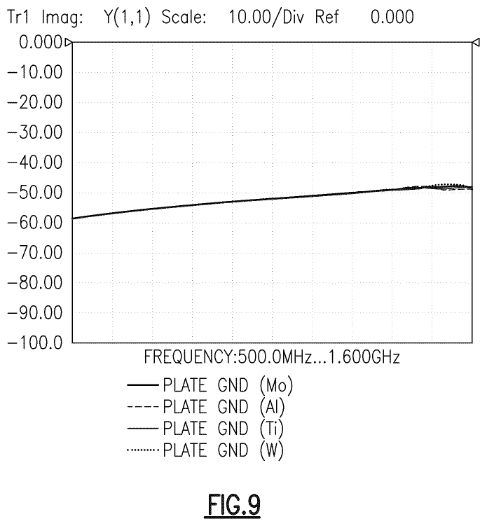

FIG. 9 is a graph showing simulated admittance results of the IDT capacitor 1a with the ground layer 34 having different materials. In the simulations of FIG. 9, a molybdenum layer, an aluminum layer, a titanium layer, and a tungsten layer as the ground layer 34 are compared. FIG. 9 indicates that the acoustic response can be affected by the material of the ground layer 34. Therefore, the material of the ground layer 34 can be selected based at least in part on the desired acoustic response.

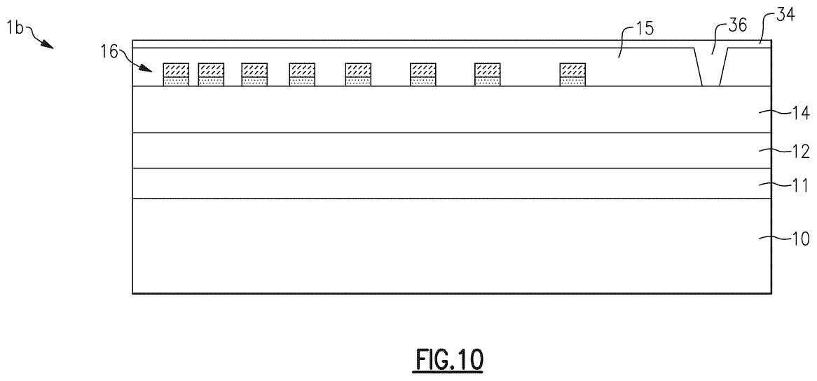

FIG. 10 is a schematic cross-sectional side view of an IDT capacitor 1b according to an embodiment. Unless otherwise noted, the components shown in FIG. 10 may be structurally and/or functionally the same as or generally similar to like components disclosed herein. In the IDT capacitor 1b, the ground structure can include the insulator 15, the ground layer 34, and a conductive via 36. The ground layer 34 can be electrically connected to a ground line formed with or near the piezoelectric layer 14 at least partially through a conductive path, such as the conductive via 36. The conductive via 36 is electrically connected to the ground layer 34. The conductive via 36 can extend at least partially (e.g., fully) through a thickness of the insulator 15. Although a filled via is illustrated in FIG. 10, the conductive via can have any suitable via type, such as a conformal via.

FIG. 11 is a schematic cross-sectional side view of an IDT capacitor 1c according to an embodiment. Unless otherwise noted, the components shown in FIG. 11 may be structurally and/or functionally the same as or generally similar to like components disclosed herein. In some embodiments, the ground layer 34 may be provided along a sidewall of the insulator 15 so as to be electrically connected to a ground line formed with or near the piezoelectric layer 14. For example, the ground layer 34 can be conformally provided over the insulator 15 and an end of the ground layer 34 can be electrically connected to the ground line.

Any suitable combinations of two or more features disclosed herein can be made in various forms. An acoustic wave device (e.g., an IDT capacitor) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more IDT capacitors disclosed herein. FR1 can be from 410 MHz to 7.125 GHz, for example, as specified in a current 5G NR specification. One or more IDT capacitors in accordance with any suitable principles and advantages disclosed herein can be included in a filter arranged to filter a radio frequency signal in a 4G LTE operating band and/or in a filter having a passband that includes a 4G LTE operating band and a 5G NR operating band.

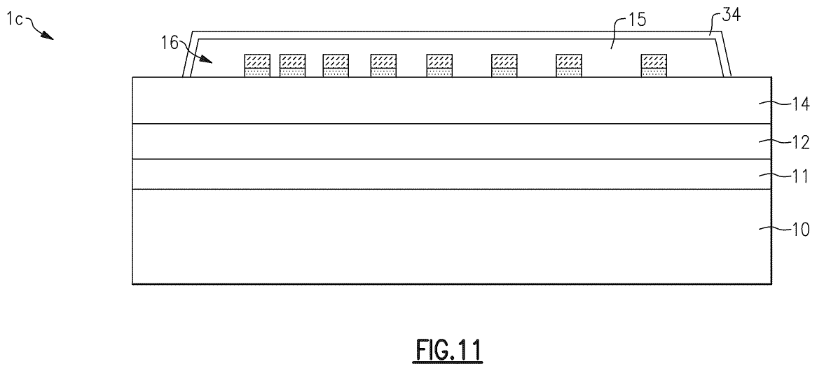

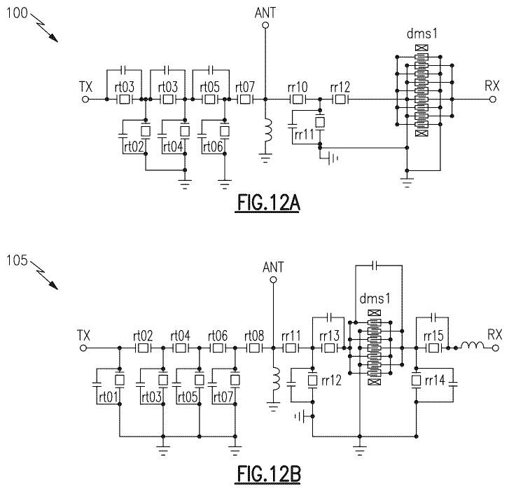

FIG. 12A is a schematic diagram of an example multiplexer 100 that includes surface acoustic wave devices according to an embodiment. The multiplexer 100 can be a duplexer. The multiplexer 100 includes a transmit filter and a receive filter. For example, the transmit filter can be a band pass filter. The illustrated transmit filter in the multiplexer 100 is arranged to filter a radio frequency signal received at a transmit port TX and provide a filtered output signal to an antenna port ANT. The illustrated receive filter in the multiplexer 100 is arranged to filter a radio frequency signal received at the antenna port ANT and provide a filtered output to a receive port RX. The transmit filter includes resonators rt01 to rt07. The resonators rt01, rt03, rt05 are series resonators and rt02, rt04, rt06 are shunt resonators. The receive filter includes resonators rr10, rr11, rr12, and a multi-mode SAW filter (e.g., a double mode SAW filter dms1). The resonators rr10, rr12 are series resonators and the resonator rr11 is a shunt resonator.

The multiplexer 100 also includes capacitors coupled in parallel with the resonators rt01, rt02, rt03, rt04, rt05, rt06, rr11. The capacitors can include one or more IDT capacitors in accordance with any suitable principles and advantages disclosed herein. The transmit filter and the receive filter of the multiplexer 100 can have a relatively small gap between passbands. Using IDT capacitors disclosed herein can reduce the impact of one or more capacitors from the transmit filter on the passband of the receive filter and/or reduce the impact of one or more capacitors of the receive filter on the transmit filter. Also, the IDT capacitors disclosed herein can enable size reduction of the multiplexer 100.

FIG. 12B is a schematic diagram of another multiplexer 105 that includes surface acoustic wave devices according to an embodiment. The multiplexer 105 can be a duplexer. The multiplexer 105 includes a transmit filter and a receive filter. For example, the transmit filter can be a band pass filter. The illustrated transmit filter in the multiplexer 105 is arranged to filter a radio frequency signal received at a transmit port TX and provide a filtered output signal to an antenna port ANT. The illustrated receive filter in the multiplexer 105 is arranged to filter a radio frequency signal received at the antenna port ANT and provide a filtered output to a receive port RX. The transmit filter includes resonators rt01 to rt08. The resonators rt02, rt04, rt06, rt08 are series resonators and rt01, rt03, rt05, rt07 are shunt resonators. The receive filter includes resonators rr11 to rr15, and a multi-mode SAW filter (e.g., a double mode SAW filter dms1). The resonators rr11, rr13, rr15 are series resonators and the resonators rr12, rr14 are shunt resonators.

The multiplexer 105 also includes capacitors coupled in parallel with the resonators rt01, rt03, rt05, rt07, rr12, rr13, rr14, rr15 and with the DMS filter dms1. The capacitors can include one or more IDT capacitors in accordance with any suitable principles and advantages disclosed herein.

Any suitable filter topology can include an IDT capacitor in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

FIG. 13 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 13 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 179B can serve, for example, as an input contact and an output contact. The SAW component 176 and the other circuitry 177 are on a common packaging substrate 180 in FIG. 13. The packaging substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

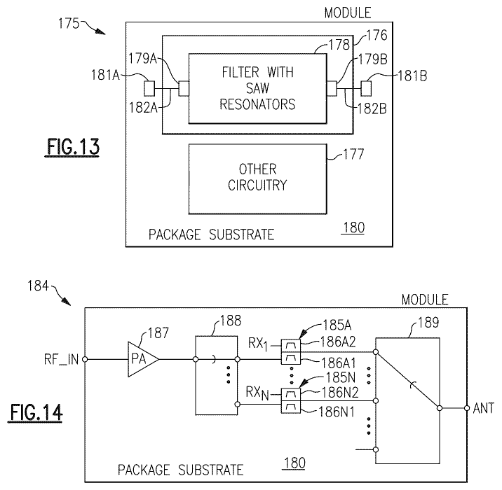

FIG. 14 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate 180 can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 14 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

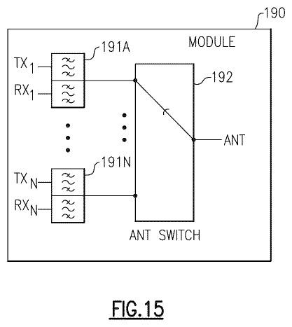

FIG. 15 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

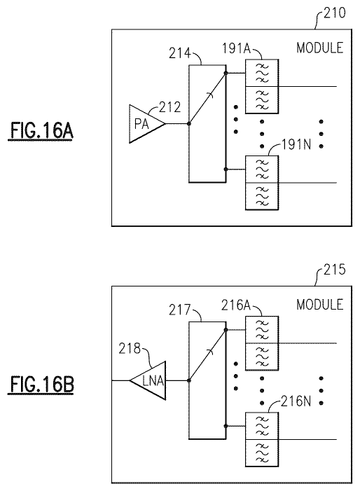

FIG. 16A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 16B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

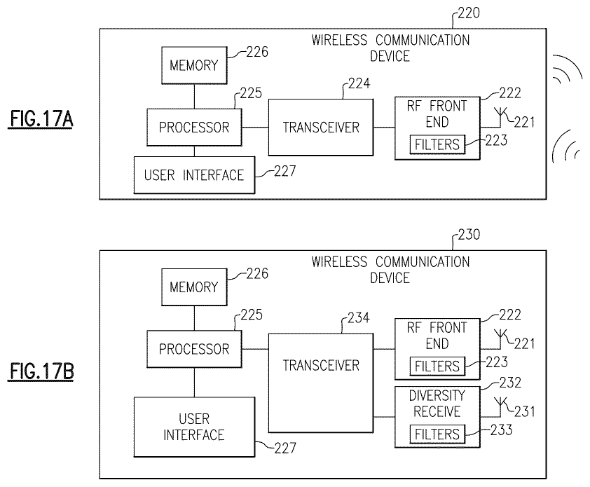

FIG. 17A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 17B is a schematic diagram of a wireless communication device 230 that includes filters 223 in a radio frequency front end 222 and a second filter 233 in a diversity receive module 232. The wireless communication device 230 is like the wireless communication device 220 of FIG. 17A, except that the wireless communication device 230 also includes diversity receive features. As illustrated in FIG. 17B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An interdigital transducer capacitor comprising:
a piezoelectric layer;
a ground structure including an insulator and a conductive ground layer, the insulator positioned between the piezoelectric layer and the conductive ground layer; and
an interdigital transducer electrode between at least a portion of the piezoelectric layer and the ground structure.

2. The interdigital transducer capacitor of claim 1 wherein the insulator has a Young's modulus greater than 80 GPa.

3. The interdigital transducer capacitor of claim 1 wherein the insulator is a polyimide layer.

4. The interdigital transducer capacitor of claim 1 wherein the insulator is a polycrystalline lithium niobate layer.

5. The interdigital transducer capacitor of claim 1 wherein the insulator has a thickness in a range between 100 nm and 500 nm.

6. The interdigital transducer capacitor of claim 1 wherein the insulator is in contact with the piezoelectric layer.

7. The interdigital transducer capacitor of claim 1 wherein the conductive ground layer includes molybdenum, aluminum, titanium, or tungsten.

8. The interdigital transducer capacitor of claim 1 wherein the conductive ground layer and the interdigital transducer electrode include a same material.

9. The interdigital transducer capacitor of claim 1 wherein the conductive ground layer has a thickness in a range between 50 nm and 300 nm.

10. The interdigital transducer capacitor of claim 1 wherein the conductive ground layer is positioned on a surface of the insulator.

11. The interdigital transducer capacitor of claim 1 wherein the conductive ground layer conformally covers the insulator.

12. The interdigital transducer capacitor of claim 1 further includes a conductive via at least partially through a thickness of the insulator and electrically connected to the conductive ground layer.

13. The interdigital transducer capacitor of claim 1 wherein the interdigital transducer electrode is in electrical communication with the piezoelectric layer.

14. The interdigital transducer capacitor of claim 1 wherein the interdigital transducer electrode is pitch modulated.

15. The interdigital transducer capacitor of claim 1 further comprising a support substrate, wherein the piezoelectric layer is positioned between the support substrate and the insulator.

16. The interdigital transducer capacitor of claim 15 further comprising an intermediate layer between the support substrate and the piezoelectric layer.

17. An interdigital transducer capacitor comprising:
a piezoelectric layer;
an insulator over the piezoelectric layer;
a conductive layer over the insulator; and
an interdigital transducer electrode between at least a portion of the piezoelectric layer and the insulator.

18. The interdigital transducer capacitor of claim 17 wherein the insulator has a Young's modulus greater than 80 GPa.

19. The interdigital transducer capacitor of claim 17 wherein the interdigital transducer electrode is pitch modulated.

20. A filter having a capacitor region and a resonator region, the filter comprising:
an interdigital transducer capacitor in the capacitor region, the interdigital transducer capacitor including a piezoelectric layer, a ground structure, and an interdigital transducer electrode, the ground structure including an insulator and a conductive ground layer, the insulator being positioned between the piezoelectric layer and the conductive ground layer, and the interdigital transducer electrode being positioned between at least a portion of the piezoelectric layer and the ground structure; and
a surface acoustic wave resonator in the resonator region electrically coupled to the interdigital transducer capacitor.
